(19) United States
(12) Patent Application Publication
(10) Pub. No.: US 2023/0154816 A1
(43) Pub. Date: May 18, 2023

(54) THERMAL BYPASS FOR STACKED DIES

(71) Applicant: ADEIA SEMICONDUCTOR BONDING TECHNOLOGIES INC., San Jose, CA (US)

(72) Inventors: Belgacem Haba, Saratoga, CA (US); Christopher Aubuchon, Palo Alto, CA (US)

(21) Appl. No.: 18/055,798

(22) Filed: Nov. 15, 2022

Related U.S. Application Data
(60) Provisional application No. 63/264,214, filed on Nov. 17, 2021.

(51) Int. Cl. H01L 23/36; H01L 23/00

(52) U.S. Cl. CPC H01L 23/36; H01L 24/32; H01L 24/08; H01L 2224/32221; H01L 2224/08145

(57) ABSTRACT

The disclosed technology relates to microelectronic devices that can dissipate heat efficiently. In some aspects, such a microelectronic device includes a first semiconductor element and at least one second semiconductor element disposed on the first semiconductor element. Such a microelectronic device may further include a thermal block disposed on the first semiconductor element and adjacent to the at least one second semiconductor element. The thermal block may include a conductive thermal pathway to transfer heat from the first semiconductor element to a heat sink disposed on the thermal block. In some embodiments, a coefficient of thermal expansion (CTE) of the thermal block is less than 10 μm/m° C. In some embodiments, a thermal conductivity of the thermal block is higher than 150 Wm-1K-1. at room temperature.

### CROSS-REFERENCE TO RELATED APPLICATIONS

This application claims priority to U.S. Provisional Application No. 63/264,214, filed Nov. 17, 2021, titled “THERMAL BYPASS FOR STACKED DIES”, the content of which is incorporated by reference in its entirety.

### BACKGROUND

### Field

The field relates to dissipating heat in microelectronics, and particularly in microelectronics formed of directly bonded elements.

### Description of the Related Art

With the miniaturization and the high density integration of electronic components, the heat flux density in microelectronics is increasing. If the heat generated during the operation of microelectronics is not dissipated, the microelectronics may shut down or burn out. In particular, thermal dissipation is a serious problem in high-power devices and/or stacked devices.

### BRIEF DESCRIPTION OF THE DRAWINGS

Specific implementations will now be described with reference to the following drawings, which are provided by way of example, and not limitation.

FIG. 1 schematically illustrates a cross-sectional view of an example microelectronic system according to some embodiments of the disclosed technology.

FIG. 2 schematically illustrate a plan view of the example microelectronic system shown in FIG. 1.

FIG. 3 schematically illustrates a cross-sectional view of another example microelectronic system according to some embodiments of the disclosed technology.

### DETAILED DESCRIPTION

Microelectronic elements (e.g., dies/chips) can be stacked and bonded to one another to form a device. It is difficult to dissipate heat in a device with chip stacking, especially as chips get thinner. The use of chip joining methods such as adhesive bonding can make heat dissipation in the device less effective, as the adhesives may reduce or insulate heat transfer. Moreover, it is difficult to specifically lower the temperature in a desired portion of the device. For example, when packaging stacks of dies, heat dissipation is typically aided by heat sinks at the top of the stack, but extracting heat from lower dies is challenging. Especially in high power chips, thermal dissipation can be a serious problem. Accordingly, there remains a continuing need for improved techniques to dissipate heat in microelectronic devices.

Methods and structures are provided for redirecting thermal paths from lower dies in a stack to upper heat dissipation structures, such as heat sinks. For example, a microelectronic device 100 may include thermal blocks/heat blocks 137 which can redirect the heat flow in the device, thus reducing the heat flow through a certain chip (e.g., 101 and 102) or particular region(s) of a chip in the device. In some embodiments, a microelectronic device 100 may include one thermal block. In other embodiments, a microelectronic device 100 may include multiple thermal blocks spaced apart from one another. For example, the thermal block 137 may include a conductive thermal pathway to transfer heat from a bottom semiconductor element 1000 to a heat sink 131 disposed on top of the thermal block 137. Such a thermal block 137 (or thermal bypass) may occupy only a small footprint in a device 100. In some embodiments, the thermal block 137 can be devoid of active circuitry (e.g., devoid of transistors). In other embodiments, it can also be devoid of passive circuits.

In some embodiments, a thermal block 137 is directly bonded to another element (e.g., a lower die 1000) in the device 100, thus avoiding the use of adhesives which may reduce heat transfer. The coefficient of thermal expansion (CTE) of the thermal block 137 may be chosen to substantially match with the CTE of that element, to avoid fractures or cracks in the bonded structure when the temperature rises during operation of the device 100. For example, the element to which the thermal block 137 is directly bonded to (e.g., the lower die 1000) may be formed of silicon and the thermal block material may have a CTE similar to that of silicon.

In some embodiments, the thermal block 137 is formed of a high thermal conductivity material (e.g., a material having a higher thermal conductivity than that of silicon or copper, at least at around the device operating temperature, e.g., about 0-40° C.). The thermal conductivity of the thermal block 137 may be higher than that of a neighboring chip (e.g., 101 and 102), thus redirecting the heat flow in the device 100 and reducing the heat flow through that neighboring chip (e.g., 101 and 102). For example, the thermal block 137 may comprise a single crystal diamond block, a nano-fiber block, or a nano-porous metal (e.g., tungsten (W)) filled block.

In one example, a stacked system 100 may include a thermal path unit 137 attached directly (e.g., directly bonded without an adhesive) to a bottom element 1000 (which may have a high temperature during operation) by way of direct bonding (e.g., nonconductive direct bonding or hybrid bonding in which nonconductive regions are directly bonded to one another and conductive features are directly bonded to one another). The thermal path unit 137 may be adjacent to at least one chip, e.g, first die 101. The thermal path unit 137 may be connected to a top thermal sink 131. The thermal path unit 137 may have a CTE under 10 μm/m° C. (or close to that of Si) and a thermal conductivity higher than that of copper (e.g., many times of copper). Thus, heat flux in the stacked system 100 can be redirected, so that the heat flux through the thermal block 137 is larger than the heat flux through the first die 101. Therefore, a non-limiting advantage of the disclosed technology is that most of the heat bypasses the operational die(s), e.g., the first die 101 and/or the second die 102, so as to not negatively affect their operation.

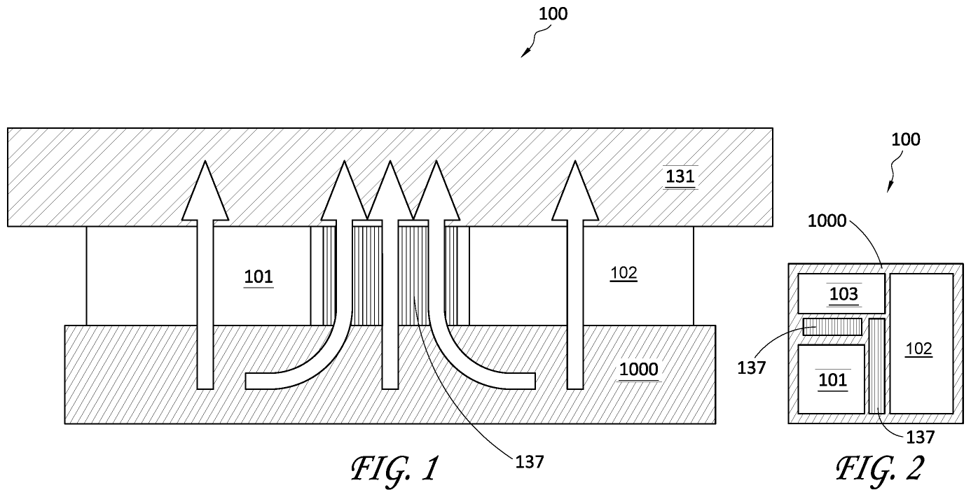

FIG. 1 and FIG. 2 schematically illustrate a cross-sectional view and a plan view of an example microelectronic system 100 having stacked semiconductor elements (e.g., dies/chips) and a thermal block 137 (or thermal bypass) which connects to a heat sink 131 (e.g., a metal heat sink or a heat pipe with fluid coolant) at the top of the stack. The heat generated by the semiconductor elements during operation may be transferred to the heat sink and dissipated away from the system as illustrated by the arrows. For example, the thermal block 137 may include a conductive thermal pathway to transfer heat from a bottom semiconductor element/base element 1000 to a heat sink 131 disposed on top of the thermal block 137. The thermal block 137 and one or a plurality of chips (e.g., “first die” 101, “second die” 102 and “third die” 103) may be mounted on a base element 1000, which can be a die, wafer, etc. The thermal block 137 may be adjacent to at least one chip (e.g., at least “first die” 101) and thus reducing heat flow through the at least one chip. In other embodiments, the thermal block 137 may also be adjacent to additional chips disposed on the base element 1000. For example, the thermal block 137 may also be adjacent to the second die 102 and/or the third die 103. In use, a method of operating the microelectronic system 100 may include directing a heat flux through the thermal block 137 that is disposed on the base element 1000 and a heat flux through the first die 101 (or the second die 102), such that the heat flux through the thermal block 137 is larger than the heat flux through the first die 101 (or the second die 102).

In some embodiments, the thermal block 137 has a CTE very close to that of the base element 1000. For example, the thermal block 137 may have a CTE close to that of silicon (Si). In one example, the thermal block 137 may have a CTE lower than that of copper at least at around the device operating temperature, or no more than (e.g., less than) 10 μm/m° C., no more than 9 μm/m° C., no more than 8 μm/m° C., or more preferably no more than 7 μm/m° C.

In some embodiments, the thermal block 137 has a thermal conductivity greater than that of an adjacent chip (e.g., “first die”), thus reducing heat flow through the adjacent chip. For example, the adjacent chip (e.g., “first die”) may include silicon and the thermal block 137 may have a thermal conductivity greater than that of silicon. In some embodiments, the thermal block 137 has a thermal conductivity similar to that of copper or higher (e.g., about 3 times that of copper, or about 5 times that of copper). In some embodiments, the thermal block 137 has a thermal conductivity of about 1000 to 2000 Wm⁻¹ K⁻¹ at room temperature.

In some embodiments, the thermal block 137 may include diamond blocks (e.g., single crystal diamond) or alike, nano-fiber blocks, nano-porous metal (e.g., W) filled blocks, graphite, or GeSe. In some embodiments, the thermal block 137 may be formed of an electrically non-conducting or semiconducting material, for example non-metal. In various embodiments, the thermal block 137 is formed of materials that have both a low CTE (e.g., lower than 10 μm/m° C., e.g., lower than 8 μm/m° C. or lower than 7 μm/m° C.) and a thermal conductivity higher than that of Si at least at around the device operating temperature (for example, the thermal block may have a thermal conductivity higher than 100 Wm⁻¹ K⁻¹, e.g., higher than 150 Wm⁻¹ K⁻¹, at room temperature).

In some embodiments, the thermal block 137 may be mounted to base element 1000 by way of direct bonding without an intervening adhesive, such as nonconductive direct bonding techniques or hybrid direct bonding techniques. For example, the thermal block 137 can be mounted using the ZIBOND® and/or DBI® processes configured for room temperature, atmospheric pressure direct bonding or the DBI® Ultra process configured for low-temperature hybrid bonding, which are commercially available from Adeia of San Jose, Calif. In some embodiments, the thermal block 137 may be mounted to the bottom chip by way of solder bonding or adhesive bonding. In some embodiments, the thermal block may be mounted to the bottom chip via a thermal interface material (TIM).

In some embodiments, the stacked semiconductor elements can be directly bonded to each other without an intervening adhesive. For example, “first die” 101, “second die” 102 and/or “third die” 103 may be directly bonded (e.g., direct hybrid bonded) to the base element 1000. In some embodiments, the top heat sink may be directly bonded to the semiconductor elements (e.g., “first die” 101, “second die” 102 and/or “third die” 103) and/or the thermal block 137, or may be mounted to the semiconductor elements and/or the thermal block via a TIM. For example the direct bonding process may include the ZIBOND® and DBI® processes configured for room temperature, atmospheric pressure direct bonding or the DBI® Ultra process configured for low-temperature hybrid bonding, which are commercially available from Adeia of San Jose, Calif. The direct bonds can be between dielectric materials of the bonded elements and, in some embodiments, can also include conductive materials at or near the bond interface for direct hybrid bonding. The conductive materials at the bonding interface may be bonding pads formed in or over a redistribution layer (RDL) over a die, and/or passive electronic components.

For example, a microelectronic device may include a first semiconductor element; at least one second semiconductor element disposed on the first semiconductor element; and a thermal block disposed on the first semiconductor element and adjacent to the at least one second semiconductor element, the thermal block comprising a conductive thermal pathway to transfer heat from the first semiconductor element to a heat sink disposed on the thermal block, wherein a coefficient of thermal expansion (CTE) of the thermal block is less than 10 μm/m° C., and wherein a thermal conductivity of the thermal block is higher than 150 Wm⁻¹ K⁻¹ at room temperature. The thermal block is configured to reduce a heat flow through the at least one second semiconductor element. The at least one second semiconductor element may comprise silicon, and a thermal conductivity of the thermal block at around the device operating temperature is higher than that of silicon, such that a heat flux through the thermal block is larger than that through the at least one second semiconductor element during operation of the microelectronic device.

In one embodiment, a coefficient of thermal expansion (CTE) of the thermal block is substantially similar to a CTE of the first semiconductor element. In one embodiment, the first semiconductor element comprises silicon, and wherein a coefficient of thermal expansion (CTE) of the thermal block is substantially similar to the CTE of silicon. In one embodiment, a coefficient of thermal expansion (CTE) of the thermal block is lower than that of copper. In one embodiment, a coefficient of thermal expansion (CTE) of the thermal block is lower than 7 μm/m° C. In one embodiment, a thermal conductivity of the thermal block is higher than that of the at least one second semiconductor element. In one embodiment, a thermal conductivity of the thermal block is higher than that of silicon. In one embodiment, a thermal conductivity of the thermal block is higher than 200 Wm⁻¹ K⁻¹ at room temperature. In one embodiment, a thermal conductivity of the thermal block is within 10% of that of copper. In one embodiment, a thermal conductivity of the thermal block is at least three times that of copper. In one embodiment, the thermal block comprises diamond, nano-fiber, a nano-porous metal, graphite, or GeSe. In one embodiment, the thermal block is formed of an electrically non-conducting or semiconducting material.

In one embodiment, the thermal block is directly bonded to the first semiconductor element without an intervening adhesive. In one embodiment, the interface between the thermal block and the first semiconductor element comprises dielectric-to-dielectric direct bonds. In one embodiment, the thermal block is bonded to the first semiconductor element by way of solder bonding. In one embodiment, the thermal block is bonded to the first semiconductor element by way of adhesive bonding. In one embodiment, the thermal block is bonded to the first semiconductor element by a thermal interface material (TIM). In one embodiment, the at least one second semiconductor element is directly bonded to the first semiconductor element without an intervening adhesive. In one embodiment, the interface between the at least one second semiconductor element and the first semiconductor element comprises conductor-to-conductor and dielectric-to-dielectric direct bonds.

In one embodiment, the heat sink is in contact with the at least one second semiconductor element. In one embodiment, the heat sink is directly bonded to the at least one second semiconductor element without an intervening adhesive. In one embodiment, the heat sink is directly bonded to the thermal block without an intervening adhesive. In one embodiment, the first semiconductor element comprises an integrated device die. In one embodiment, the least one second semiconductor element comprises an integrated device die. In one embodiment, the thermal block is devoid of active circuitry. In one embodiment, the thermal block is further devoid of passive circuits.

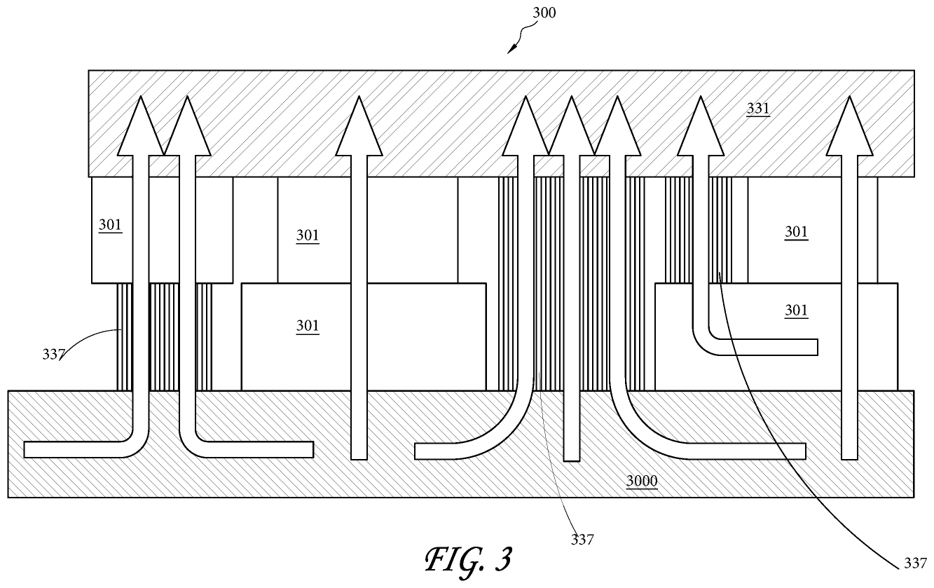

FIG. 3 schematically illustrates a cross-sectional view of another example microelectronic system 300 having stacked semiconductor elements 301 (e.g., dies/chips), several thermal blocks 337, and a heat sink 331 (e.g., a metal heat sink or a heat pipe with fluid coolant) at the top of the stack. The thermal blocks 337 can be arranged in a variety of ways. In some embodiments, a thermal block 337 can extend from the bottom element 3000 to an upper die that is connected to the heat sink 331. In other embodiments, a thermal block 337 can extend from the bottom element 3000 directly to the heat sink 331. In further embodiments, a thermal block 337 can extend from a lower die (which is mounted on the bottom element 3000) to the heat sink 331. The thermal blocks 337 can redirect heat flow in the system as indicated by the arrows, thus reducing heat flow through their adjacent/neighboring chips.

For example, a microelectronic device may include a first integrated device die; a second integrated device die disposed on the first integrated device die; a heat block directly bonded to the first integrated device die without an adhesive; and a heat sink disposed over at least the heat block. In one embodiment, the heat block comprises a conductive thermal pathway to transfer heat from the first integrated device die to the heat sink. In one embodiment, the heat block is configured to reduce a heat flow through the second integrated device die. In one embodiment, the second integrated device die comprises silicon, and wherein a thermal conductivity of the heat block is higher than that of silicon. In one embodiment, a coefficient of thermal expansion (CTE) of the heat block is lower than 10 μm/m° C. In one embodiment, a heat flux through the heat block is larger than that through the second integrated device die during operation of the microelectronic device. In one embodiment, the second integrated device die is directly bonded to the first integrated device die without an adhesive.

In another example, a microelectronic device may include a first integrated device die; a second integrated device die disposed on the first integrated device die; a heat block disposed on the first integrated device die; and a heat sink disposed over at least the heat block, wherein a heat flux through the heat block is larger than that through the second integrated device die during operation of the microelectronic device. In one embodiment, a coefficient of thermal expansion (CTE) of the heat block is lower than 10 μm/m° C., and wherein a thermal conductivity of the heat block is higher than that of silicon. In one embodiment, the second integrated device die is directly bonded to the first integrated device die without an adhesive. In one embodiment, the heat block is directly bonded to the first integrated device die without an adhesive.

A method of forming a microelectronic device disclosed herein may include: providing a first semiconductor element; bonding a second semiconductor element and a thermal block to the first semiconductor element; and providing a heat sink over the thermal block, the thermal block providing a thermal pathway between the first semiconductor element and the heat sink, wherein a coefficient of thermal expansion (CTE) of the thermal block is less than 10 μm/m° C., and wherein a thermal conductivity of the thermal block is higher than 150 Wm⁻¹ K⁻¹ at room temperature. In one embodiment, the second semiconductor element is directly bonded to the first semiconductor element without an intervening adhesive. In one embodiment, the thermal block is directly bonded to the first semiconductor element without an intervening adhesive.

A method of operating a microelectronic device comprising a first integrated device die and a second integrated device die disposed on the first integrated device die may include: directing a first heat flux through a heat block disposed on the first integrated device die and a second heat flux through the second integrated device die, wherein the first heat flux through the heat block is larger than the second heat flux through the second integrated device die. In one embodiment, a coefficient of thermal expansion (CTE) of the heat block is lower than 10 μm/m° C., and wherein a thermal conductivity of the heat block is higher than that of silicon. In one embodiment, a heat sink is disposed over at least the heat block.

### Electronic Elements

A die can refer to any suitable type of integrated device die. For example, the integrated device dies can comprise an electronic component such as an integrated circuit (such as a processor die, a controller die, or a memory die), a microelectromechanical systems (MEMS) die, an optical device, or any other suitable type of device die. In some embodiments, the electronic component can comprise a passive device such as a capacitor, inductor, or other surface-mounted device. Circuitry (such as active components like transistors) can be patterned at or near active surface(s) of the die in various embodiments. The active surface may be on a side of the die which is opposite the backside of the die. The backside may or may not include any active circuitry or passive devices.

An integrated device die can comprise a bonding surface and a back surface opposite the bonding surface. The bonding surface can have a plurality of conductive bond pads including a conductive bond pad, and a non-conductive material proximate to the conductive bond pad. In some embodiments, the conductive bond pads of the integrated device die can be directly bonded to the corresponding conductive pads of the substrate or wafer without an intervening adhesive, and the non-conductive material of the integrated device die can be directly bonded to a portion of the corresponding non-conductive material of the substrate or wafer without an intervening adhesive. Directly bonding without an adhesive is described throughout U.S. Pat. Nos. 7,126,212; 8,153,505; 7,622,324; 7,602,070; 8,163,373; 8,389,378; 7,485,968; 8,735,219; 9,385,024; 9,391,143; 9,431,368; 9,953,941; 9,716,033; 9,852,988; 10,032,068; 10,204,893; 10,434,749; and 10,446,532, the contents of each of which are hereby incorporated by reference herein in their entirety and for all purposes.

### Examples of Direct Bonding Methods and Directly Bonded Structures

Various embodiments disclosed herein relate to directly bonded structures in which two elements can be directly bonded to one another without an intervening adhesive. Two or more electronic elements, which can be semiconductor elements (such as integrated device dies, wafers, etc.), may be stacked on or bonded to one another to form a bonded structure. Conductive contact pads of one element may be electrically connected to corresponding conductive contact pads of another element. Any suitable number of elements can be stacked in the bonded structure. The contact pads may comprise metallic pads formed in a nonconductive bonding region, and may be connected to underlying metallization, such as a redistribution layer (RDL).

In some embodiments, the elements are directly bonded to one another without an adhesive. In various embodiments, a non-conductive or dielectric material of a first element can be directly bonded to a corresponding non-conductive or dielectric field region of a second element without an adhesive. The non-conductive material can be referred to as a nonconductive bonding region or bonding layer of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. Suitable dielectric materials for direct bonding include but are not limited to inorganic dielectrics, such as silicon oxide, silicon nitride, or silicon oxynitride, or can include carbon, such as silicon carbide, silicon oxycarbonitride, silicon carbonitride or diamond-like carbon. In some embodiments, the dielectric materials do not comprise polymer materials, such as epoxy, resin or molding materials.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid direct bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments in the bonding tool described herein and, subsequently, the bonded structure can be annealed. Annealing can be performed in a separate apparatus. Upon annealing, the contact pads can expand and contact one another to form a metal-to-metal direct bond. Beneficially, the use of hybrid bonding techniques, such as Direct Bond Interconnect, or DBI®, available commercially from Xperi of San Jose, Calif., can enable high density of pads connected across the direct bond interface (e.g., small or fine pitches for regular arrays). In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 5 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. In embodiments described herein, whether a die or a substrate, the first element can be considered a host substrate and is mounted on a support in the bonding tool to receive the second element from a pick-and-place or robotic end effector. The second element of the illustrated embodiments comprises a die. In other arrangements, the second element can comprise a carrier or a flat panel. or substrate (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness. For example, the bonding layers may have a surface roughness of less than 2 nm root mean square (RMS) per micron, or less than 1 nm RMS per micron.

In various embodiments, metal-to-metal bonds between the contact pads in direct hybrid bonded structures can be joined such that conductive features grains, for example copper grains on the conductive features grow into each other across the bond interface. In some embodiments, the copper can have grains oriented along the 111 crystal plane for improved copper diffusion across the bond interface. The bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in US 2019/0096741, which is incorporated by reference herein in its entirety and for all purposes.

In one aspect, the disclosed technology relates to a microelectronic device comprising: a first semiconductor element; at least one second semiconductor element disposed on the first semiconductor element; and a thermal block disposed on the first semiconductor element and adjacent to the at least one second semiconductor element, the thermal block comprising a conductive thermal pathway to transfer heat from the first semiconductor element to a heat sink disposed on the thermal block, wherein a coefficient of thermal expansion (CTE) of the thermal block is less than 10 μm/m° C., and wherein a thermal conductivity of the thermal block is higher than 150 Wm⁻¹ K⁻¹ at room temperature.

In one embodiment, the thermal block is configured to reduce a heat flow through the at least one second semiconductor element.

In one embodiment, the at least one second semiconductor element comprises silicon, and wherein a thermal conductivity of the thermal block at around the device operating temperature is higher than that of silicon.

In one embodiment, a heat flux through the thermal block is larger than that through the at least one second semiconductor element during operation of the microelectronic device.

In one embodiment, a coefficient of thermal expansion (CTE) of the thermal block is substantially similar to a CTE of the first semiconductor element.

In one embodiment, the first semiconductor element comprises silicon, and wherein a coefficient of thermal expansion (CTE) of the thermal block is substantially similar to the CTE of silicon.

In one embodiment, a coefficient of thermal expansion (CTE) of the thermal block is lower than that of copper.

In one embodiment, a coefficient of thermal expansion (CTE) of the thermal block is lower than 7 μm/m° C.

In one embodiment, a thermal conductivity of the thermal block is higher than that of the at least one second semiconductor element.

In one embodiment, a thermal conductivity of the thermal block is higher than that of silicon.

In one embodiment, a thermal conductivity of the thermal block is higher than 200 Wm⁻¹ K⁻¹ at room temperature.

In one embodiment, a thermal conductivity of the thermal block is within 10% of that of copper.

In one embodiment, a thermal conductivity of the thermal block is at least three times that of copper.

In one embodiment, the thermal block comprises diamond, nano-fiber, a nano-porous metal, graphite, or GeSe.

In one embodiment, the thermal block is formed of an electrically non-conducting or semiconducting material.

In one embodiment, the thermal block is directly bonded to the first semiconductor element without an intervening adhesive.

In one embodiment, the interface between the thermal block and the first semiconductor element comprises dielectric-to-dielectric direct bonds.

In one embodiment, the thermal block is bonded to the first semiconductor element by way of solder bonding.

In one embodiment, the thermal block is bonded to the first semiconductor element by way of adhesive bonding.

In one embodiment, the thermal block is bonded to the first semiconductor element by a thermal interface material (TIM).

In one embodiment, the at least one second semiconductor element is directly bonded to the first semiconductor element without an intervening adhesive.

In one embodiment, the interface between the at least one second semiconductor element and the first semiconductor element comprises conductor-to-conductor and dielectric-to-dielectric direct bonds.

In one embodiment, the heat sink is in contact with the at least one second semiconductor element.

In one embodiment, the heat sink is directly bonded to the at least one second semiconductor element without an intervening adhesive.

In one embodiment, the heat sink is directly bonded to the thermal block without an intervening adhesive.

In one embodiment, the first semiconductor element comprises an integrated device die.

In one embodiment, the least one second semiconductor element comprises an integrated device die.

In one embodiment, the thermal block is devoid of active circuitry.

In one embodiment, the thermal block is further devoid of passive circuits.

In another aspect, the disclosed technology relates to a method of forming a microelectronic device, the method comprising: providing a first semiconductor element; bonding a second semiconductor element and a thermal block to the first semiconductor element; and providing a heat sink over the thermal block, the thermal block providing a thermal pathway between the first semiconductor element and the heat sink, wherein a coefficient of thermal expansion (CTE) of the thermal block is less than 10 μm/m° C., and wherein a thermal conductivity of the thermal block is higher than 150 Wm⁻¹ K⁻¹ at room temperature.

In one embodiment, the second semiconductor element is directly bonded to the first semiconductor element without an intervening adhesive.

In one embodiment, the thermal block is directly bonded to the first semiconductor element without an intervening adhesive.

In another aspect, the disclosed technology relates to a microelectronic device comprising: a first integrated device die; a second integrated device die disposed on the first integrated device die; a heat block directly bonded to the first integrated device die without an adhesive; and a heat sink disposed over at least the heat block. In one embodiment, the heat block comprises a conductive thermal pathway to transfer heat from the first integrated device die to the heat sink.

In one embodiment, the heat block is configured to reduce a heat flow through the second integrated device die.

In one embodiment, the second integrated device die comprises silicon, and wherein a thermal conductivity of the heat block is higher than that of silicon.

In one embodiment, a coefficient of thermal expansion (CTE) of the heat block is lower than 10 μm/m° C.

In one embodiment, a heat flux through the heat block is larger than that through the second integrated device die during operation of the microelectronic device.

In one embodiment, the second integrated device die is directly bonded to the first integrated device die without an adhesive.

In another aspect, the disclosed technology relates to a microelectronic device comprising: a first integrated device die; a second integrated device die disposed on the first integrated device die; a heat block disposed on the first integrated device die; and a heat sink disposed over at least the heat block, wherein a heat flux through the heat block is larger than that through the second integrated device die during operation of the microelectronic device.

In one embodiment, a coefficient of thermal expansion (CTE) of the heat block is lower than 10 μm/m° C., and wherein a thermal conductivity of the heat block is higher than that of silicon.

In one embodiment, the second integrated device die is directly bonded to the first integrated device die without an adhesive.

In one embodiment, the heat block is directly bonded to the first integrated device die without an adhesive.

In another aspect, the disclosed technology relates to method of operating a microelectronic device comprising a first integrated device die and a second integrated device die disposed on the first integrated device die, the method comprising: directing a first heat flux through a heat block disposed on the first integrated device die and a second heat flux through the second integrated device die, wherein the first heat flux through the heat block is larger than the second heat flux through the second integrated device die.

In one embodiment, a coefficient of thermal expansion (CTE) of the heat block is lower than 10 μm/m° C., and wherein a thermal conductivity of the heat block is higher than that of silicon.

In one embodiment, a heat sink is disposed over at least the heat block.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A microelectronic device comprising:
a first semiconductor element;
at least one second semiconductor element disposed on the first semiconductor element; and
a thermal block disposed on the first semiconductor element and adjacent to the at least one second semiconductor element, the thermal block comprising a conductive thermal pathway to transfer heat from the first semiconductor element to a heat sink disposed on the thermal block,
wherein a coefficient of thermal expansion (CTE) of the thermal block is less than 10 μm/m° C., and
wherein a thermal conductivity of the thermal block is higher than 150 Wm⁻¹ K⁻¹ at room temperature.

2. The microelectronic device of claim 1, wherein the thermal block is configured to reduce a heat flow through the at least one second semiconductor element.

3. The microelectronic device of claim 1, wherein a coefficient of thermal expansion (CTE) of the thermal block is substantially similar to a CTE of the first semiconductor element.

4. The microelectronic device of claim 1, wherein a thermal conductivity of the thermal block is higher than that of the at least one second semiconductor element.

5. The microelectronic device of claim 1, wherein the thermal block is directly bonded to the first semiconductor element without an intervening adhesive.

6. The microelectronic device of claim 1, wherein the thermal block is bonded to the first semiconductor element by way of solder bonding.

7. The microelectronic device of claim 1, wherein the thermal block is bonded to the first semiconductor element by way of adhesive bonding.

8. The microelectronic device of claim 1, wherein the thermal block is bonded to the first semiconductor element by a thermal interface material (TIM).

9. The microelectronic device of claim 1, wherein the at least one second semiconductor element is directly hybrid bonded to the first semiconductor element without an intervening adhesive.

10. A microelectronic device comprising:
a first integrated device die;
a second integrated device die disposed on the first integrated device die;
a heat block directly bonded to the first integrated device die without an adhesive; and
a heat sink disposed over at least the heat block.

11. The microelectronic device of claim 10, wherein the heat block comprises a conductive thermal pathway to transfer heat from the first integrated device die to the heat sink.

12. The microelectronic device of claim 10, wherein the heat block is configured to reduce a heat flow through the second integrated device die.

13. The microelectronic device of claim 10, wherein the second integrated device die comprises silicon, and wherein a thermal conductivity of the heat block is higher than that of silicon.

14. The microelectronic device of claim 10, wherein a coefficient of thermal expansion (CTE) of the heat block is lower than 10 μm/m° C.

15. The microelectronic device of claim 10, wherein a heat flux through the heat block is larger than that through the second integrated device die during operation of the microelectronic device.

16. The microelectronic device of claim 10, wherein the second integrated device die is directly bonded to the first integrated device die without an adhesive.

17. A microelectronic device comprising:
a first integrated device die;
a second integrated device die disposed on the first integrated device die;
a heat block disposed on the first integrated device die; and
a heat sink disposed over at least the heat block,
wherein a heat flux through the heat block is larger than that through the second integrated device die during operation of the microelectronic device.

18. The microelectronic device of claim 17, wherein a coefficient of thermal expansion (CTE) of the heat block is lower than 10 μm/m° C., and wherein a thermal conductivity of the heat block is higher than that of silicon.

19. The microelectronic device of claim 17, wherein the second integrated device die is directly bonded to the first integrated device die without an adhesive.

20. The microelectronic device of claim 17, wherein the heat block is directly bonded to the first integrated device die without an adhesive.
